(19) United States
(12) Patent Application Publication
(10) Pub. No.: US 2024/0384750 A1
(43) Pub. Date: Nov. 21, 2024

(54) HINGE DEVICES AND FLEXIBLE DISPLAY DEVICES

(71) Applicant: WUHAN CHINA STAR OPTOELECTRONICS SEMICONDUCTOR DISPLAY TECHNOLOGY CO., LTD., Wuhan, Hubei (CN)

(72) Inventors: Guobao JIANG, Wuhan, Hubei (CN); Xinpeng SHAN, Wuhan, Hubei (CN)

(21) Appl. No.: 18/254,993

(22) PCT Filed: May 12, 2023
(86) PCT No.: PCT/CN2023/094060

§ 371 Date: May 30, 2023

(30) Foreign Application Priority Data
Jul. 22, 2022 (CN) 202210873458.2

(51) Int. Cl. F16C 11/04; H04M 1/02

(52) U.S. Cl. CPC F16C 11/04; H04M 1/0216; H04M 1/0268

(57) ABSTRACT

A hinge device and a flexible display device are provided according to embodiments of the present disclosure. The hinge device includes a fixed trestle, a guide slider, and a support mechanism. The guide slider is rotatably connected with the fixed trestle, and the support mechanism is rotatably connected with the fixed trestle. When the hinge device folds or unfolds, the support mechanism and the guide slider rotate relative to fixed trestle, and the support mechanism slide relative to the guide slider, so as to drive the flexible screen to fold or unfold, thereby improving folding performance and folding effect of the panel.

### TECHNICAL FIELD

The present disclosure relates to the field of designs and preparation of display devices, and in particular, to hinge devices and flexible display devices.

### BACKGROUND

With the development of technical fields of preparation of display devices, people have put forward higher requirements for the performance and quality of the display devices and display devices.

Flexible foldable display devices are applied in various fields since they can bend or fold to a certain extent. The flexible foldable display device prepared in related art requires a specific foldable structure when bending. For example, a foldable hinge is provided in the foldable display device to achieve the bending and deformation functions. When the flexible foldable device bends, the foldable hinge generally has only one rotation axis during a rotating process, a position of the rotation axis is fixed, and the fixed rotation axis cannot be well matched with other foldable components, so that linkage effect between the components of the foldable panel is reduced, thereby finally reducing folding performance of the flexible foldable display device, which is not conducive to improvement of comprehensive performance of the flexible foldable display device.

Accordingly, it is necessary to propose solutions to the problems in the related art.

### SUMMARY OF THE INVENTION

### Technical Problems

In summary, when a flexible foldable display device prepared in the related art bends and folds, a foldable hinge thereof has a fixed rotation axis, resulting in poor linkage with other foldable components, thereby reducing folding performance of the flexible foldable display device.

### Technical Solutions

In order to solve the above problems, hinge devices and flexible display devices are provided according to embodiments of the present disclosure to effectively relieve the problem of non-ideal folding effect of the flexible foldable device in a folding process in the related art, herein, the non-ideal folding effect is caused by a fixed rotation axis of the foldable hinge in the related art, which results in poor linkage with other foldable components.

In order to solve the above technical problems, technical solutions according to embodiments of the present disclosure are provided as following.

In a first aspect according to embodiments of the present disclosure, a hinge device is provided, and the hinge device includes:
a fixed trestle;
a guide slider disposed on a side of the fixed trestle and rotatably connected with the fixed trestle; and
a support mechanism disposed on a side of the fixed trestle, rotatably connected with the fixed trestle, and slidably connected with the guide slider;
herein, when the hinge device rotates, the support mechanism and the guide slider rotate relative to the fixed trestle, and the support mechanism slide relative to the guide slider; and
herein, the hinge device further includes a torsion mechanism and a middle support plate, the torsion mechanism includes a first torsion mechanism and a second torsion mechanism, and the middle support plate is disposed between the first torsion mechanism and the second torsion mechanism.

According to an embodiment of the present disclosure, the support mechanism rotates around a first virtual shaft, the guide slider connected with the support mechanism rotate around a second virtual shaft, and the first virtual shaft is parallel to the second virtual shaft.

In a second aspect according to embodiments of the present disclosure, a hinge device is provided, and the hinge device includes:
a fixed trestle;
a guide slider disposed on a side of the fixed trestle and rotatably connected with the fixed trestle; and
a support mechanism disposed on a side of the fixed trestle, rotatably connected with the fixed trestle, and slidably connected with the guide slider;
herein, when the hinge device rotates, the support mechanism and the guide slider rotate relative to the fixed trestle, and the support mechanism slide relative to the guide slider.

According to an embodiment of the present disclosure, the support mechanism rotates around a first virtual shaft, the guide slider connected with the support mechanism rotate around a second virtual shaft, and the first virtual shaft is parallel to the second virtual shaft.

According to an embodiment of the present disclosure, the guide slider is rotatably connected with the fixed trestle by a first slide chute structure;
the support mechanism is rotatably connected with the fixed trestle by a second slide chute structure; and
the first slide chute structure includes first chutes, the second slide chute structure includes limit chutes, and a curvature of each of the first chutes is different from a curvature of each of the limit chutes.

According to an embodiment of the present disclosure, the curvature of each of the first chutes ranges from 20 m⁻¹ to 30 m⁻¹, and the curvature of each of the limit chutes ranges from 15 m⁻¹ to 19 m⁻¹.

According to an embodiment of the present disclosure, a length of each of the first chutes is less than a length of each of the limit chutes.

According to an embodiment of the present disclosure, the support mechanism includes a first support mechanism and a second support mechanism disposed on a side of the first support mechanism, the first support mechanism has a first opening, the second support mechanism has a second opening, and the first opening and the second opening are dislocated.

According to an embodiment of the present disclosure, the guide slider includes a first guide slider and a second guide slider;
herein, the first guide slider is disposed in the first opening, the second guide slider is disposed in the second opening, the second virtual shaft which the first guide slider and the second guide slider rotate around changes as rotation of the support mechanism.

According to an embodiment of the present disclosure, the first guide slider and the second guide slider are each provided with the first chutes and second chutes thereon, the second chutes are disposed adjacent to the support mechanism, and the first chutes are disposed adjacent to the fixed trestle;
herein, each of the second chutes is a linear chute, and each of the first chutes is an arc-shaped chute.

According to an embodiment of the present disclosure, the first support mechanism and the second support mechanism are each provided with first rails thereon, and the fixed trestle is provided with second rails thereon;
herein, each of the second chutes on the first guide slider is mated with one of the first rails on the first support mechanism, and the first guide slider is configured to be translational with respect to the first support mechanism and along the second chutes thereon;
each of the second chutes on the second guide slider is mated with one of the first rails on the second support mechanism, and the second guide slider is configured to be translational with respect to the second support mechanism along the second chutes thereon; and
each of the first chutes on the first guide slider and the second guide slider is correspondingly mated with one of the second rails on the fixed trestle.

According to an embodiment of the present disclosure, the hinge device further includes a torsion mechanism disposed on at least one side of the fixed trestle and rotatably connected with the fixed trestle;
herein, the support mechanism slides relative to the torsion mechanism by a third slide chute structure.

According to an embodiment of the present disclosure, the torsion mechanism is provided with active grooves adjacent to the support mechanism;
herein, each of the active grooves is arc-shaped.

According to an embodiment of the present disclosure, each of the active grooves includes first arc portions and second arc portions, the second arc portions are disposed on both sides of each of first arc portions, and the second arc portions are smoothly connected with each of first arc portions;
herein, a curvature of each of the first arc portions is less than a curvature of each of the second arc portions.

According to an embodiment of the present disclosure, the torsion mechanism further includes axis pins, each of the axis pins includes an end fixed on the support mechanism and another end inserted into one of the active grooves;
herein, when the hinge device rotates, the support mechanism is configured to drive the axis pins to slide in the active grooves and to drive the torsion mechanism to move relative to the support mechanism.

According to an embodiment of the present disclosure, the torsion mechanism includes a first torsion mechanism and a second torsion mechanism opposite to the first torsion mechanism, the first torsion mechanism and the second torsion mechanism include torsion arms disposed on ends thereof, main shafts, and connection holes; and
herein, the torsion arms are provided with cams and gears, each of the cams is disposed on a side of one of the gears, and each of the cams is disposed around one of the connection holes.

According to an embodiment of the present disclosure, the cams include a first cam and a second cam, the gears include a first gear and a second gear, the first cam and the first gear are disposed on one of the torsion arms of the first torsion mechanism, and the second cam and the second gear are disposed on one of the torsion arms of the second torsion mechanism.

According to an embodiment of the present disclosure, the hinge device further includes an avoidance mechanism; herein, an end of the avoidance mechanism is connected with the fixed trestle, the avoidance mechanism is provided with a third gear and a fourth gear meshes with each other, and the third gear and the fourth gear each mesh with a corresponding one of the gears on the torsion arms;
herein, when the hinge device rotates, the first gear and the second gear on the torsion arms are configured to drive the third gear and the fourth gear to rotate, so as to make the avoidance mechanism rise or fall relative to the torsion mechanism.

According to an embodiment of the present disclosure, the torsion mechanism further includes: a third cam and a fourth cam, each of the third cam and the fourth cam being sleeved on a corresponding one of the main shafts; and
springs, each of the springs being sleeved on a corresponding one of the main shafts and abutting against one of the third cam and the fourth cam;
herein, recesses of the first cam mesh with bulges of the third cam, recesses of the second cam mesh with bulges of the fourth cam, and the bulges rotate relative to the recesses when the torsion mechanism rotates.

In a third aspect according to embodiments of the present disclosure, a flexible display device is further provided, and the flexible display device includes:
a flexible screen;
a housing configured to support the flexible screen; and
at least one hinge device, the flexible screen being laid on the hinge device, and the hinge device being connected with the housing;
herein, the hinge device includes:
a fixed trestle;
a guide slider disposed on a side of the fixed trestle and rotatably connected with the fixed trestle; and
a support mechanism disposed on a side of the fixed trestle, rotatably connected with the fixed trestle, and slidably connected with the guide slider;
herein, when the hinge device rotates, the support mechanism and the guide slider rotate relative to the fixed trestle, and the support mechanism slide relative to the guide slider.

### Beneficial Effects

In summary, beneficial effects of embodiments of the present disclosure are as followings:

In the hinge devices and the flexible display devices provided according to the embodiments of the present disclosure, the hinge device includes a fixed trestle, a support mechanism, and a rotation mechanism. Herein, an end of the rotation mechanism is fixedly connected with the support mechanism, and another end of the rotation mechanism is rotatably connected with the fixed trestle. The support mechanism is provided with guide rails, and the fixed trestle is provided with limit chutes. When the foldable hinge is in a folded state or an unfolded state, the rotation mechanism is translational with respect to the support mechanism, the guide rails of the support mechanism slide in the limit chutes, and the rotation mechanism is driven to rotate relative to the fixed trestle. During a rotating process, a rotation axis of the rotation mechanism can change. In the embodiments of the present disclosure, various components have better linkage and matching effect, which can better fold the flexible display device, and then effectively improve bending performance of the flexible display device.

### BRIEF DESCRIPTION OF THE DRAWINGS

FIG. 1 is a schematic structural view of a partial structure of a flexible foldable display device in the related art.

FIG. 2 is a schematic structural view of a partial structure of a flexible display device according to an embodiment of the present disclosure.

FIG. 3 to FIG. 5 are schematic structural views in different directions of a flexible display device according to an embodiment of the present disclosure.

FIG. 6 is a schematic structural view of a foldable hinge according to an embodiment of the present disclosure.

FIG. 7 is a schematic structural view of a partial structure of a foldable hinge according to an embodiment of the present disclosure.

FIG. 8 to FIG. 11 are schematic structural views corresponding to a support mechanism, a rotation mechanism, and a fixed trestle of a foldable hinge according to an embodiment of the present disclosure.

FIG. 12 is a schematic structural view of a foldable hinge when unfolding according to an embodiment of the present disclosure.

FIG. 13 to FIG. 15 are schematic structural views of a foldable hinge according to an embodiment of the present disclosure.

FIG. 16 and FIG. 17 are schematic structural views in different directions of a partial structure of a display device according to an embodiment of the present disclosure.

FIG. 18 is a schematic structural view of a partial structure of a display device according to an embodiment of the present disclosure.

FIG. 19 is a schematic structural view of a partial structure of another flexible display device according to an embodiment of the present disclosure.

FIG. 20 is an exposed view of a flexible display device according to an embodiment of the present disclosure.

FIG. 21 and FIG. 22 are schematic structural views of a flexible display device in different states according to an embodiment of the present disclosure.

FIG. 23 to FIG. 25 are schematic structural views in different directions of a partial structure of a flexible display device according to an embodiment of the present disclosure.

### EMBODIMENTS OF THE INVENTION

The descriptions of the following embodiments refer to the accompanying drawings to illustrate the present disclosure may be implemented.

With the continuous development of preparation technology of flexible foldable display devices, people have put forward higher requirements for the bending and folding performance of flexible display devices.

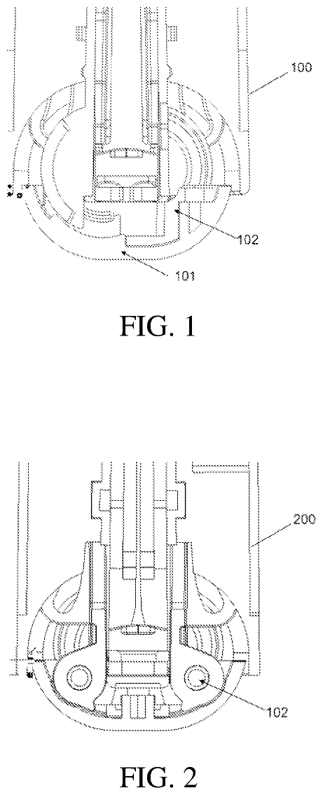

As shown in FIG. 1, FIG. 1 is a schematic structural view of a partial structure of a flexible foldable display device in the related art. When the flexible foldable display device 100 in the related art bends or folds, a hinge device is generally required to provide a drive force. The hinge device may have various structures, according to the embodiment of the present disclosure, the hinge device is illustrated by a foldable hinge 102 as an example. A flexible screen of the display device bends with the bending of the foldable hinge 102, and finally the folding of the entire flexible screen is realized. During a folding process, a fixed rotation axis correspondingly inside the foldable hinge is a fixed rotation axis. Therefore, the fixed rotation axis cannot be changed when folding, which causes that a connection cover 101 in a folding area of the flexible panel cannot rise or fall in a certain extend relative to the flexible screen, and cannot provide an avoidance space for the flexible screen in the folding area, which causes the folding performance of the flexible foldable display device to decrease, which is not conducive to the improvement of the comprehensive performance of the flexible foldable display device.

Hinge devices and flexible display devices are provided according to embodiments of the present disclosure to effectively relieve the problem of non-ideal folding performance of the flexible device in a folding process in the related art, herein, the non-ideal folding effect is caused by a fixed rotation axis of the foldable structure, which results in poor linkage with other foldable components.

As shown in FIG. 2, FIG. 2 is a schematic structural view of a partial structure of a flexible display device according to an embodiment of the present disclosure. In the embodiment of the present disclosure, a position of a rotation axil of a foldable hinge 102 can change with folding of a flexible screen during a folding process of a flexible display device, and then an avoidance space is provided to other components during the changing process, so that the linkage with other components are ensured, and the folding performance of the flexible display device is effectively improved.

In the embodiment of the present disclosure, the foldable hinge is mainly applied in display devices such as electronic devices.

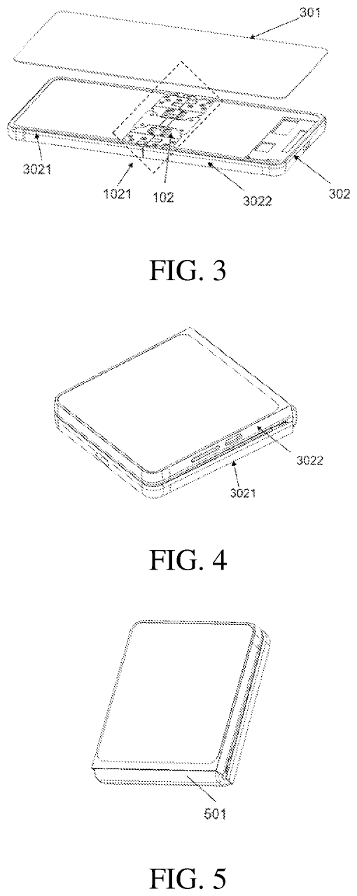

As shown in FIG. 3 to FIG. 5, FIG. 3 to FIG. 5 are schematic structural views in different directions of a flexible display device according to an embodiment of the present disclosure. Referring to FIG. 3 for detail, in the embodiment of the present disclosure, the flexible display device includes a flexible screen 301, a housing 302, and a foldable hinge 102. Herein, the foldable hinge 102 is disposed inside the housing 302 and connected with sides of the housing 302. The flexible screen 301 is laid and fixed on the housing 302 and the corresponding foldable hinge 102.

Furthermore, the foldable hinge 102 is disposed in a bending area 1021 of the flexible display device, and the housing 302 further includes a first housing 3021 and a second housing 3022. The first housing 3021 is disposed on a side of the second housing 3022. The first housing 3021 and the second housing 3022 may be disposed symmetrically relative to the bending area 1021. Herein, when the first housing 3021 and the second housing 3022 are fully unfolded, two long sides of the housing are equivalent to two middle frames of the flexible display device, thereby realizing the support of the flexible screen.

When the flexible display device bends, referring to FIG. 4 for detail, the first housing 3021 and the second housing 3022 are driven by the foldable hinge 102 to rotate relative to each other. After fully folding, the first housing 3021 and the second housing 3022 are in contact with each other, and the flexible screen 301 in an unfolded state is folded, thereby closing the foldable mobile phone to facilitate carrying.

Referring to FIG. 5 for detail, in the embodiment of the present disclosure, as rotation of the foldable hinge 102, the bending area 1021 of the flexible display device is further provided with a hinge cover 501. The hinge cover 501 can not only protect the foldable hinge 102, but also move relative to the flexible screen 301 and the housing during the folding process to form a certain avoidance space, thereby ensuring movements of other components and effectively improving comprehensive performance of the flexible foldable device.

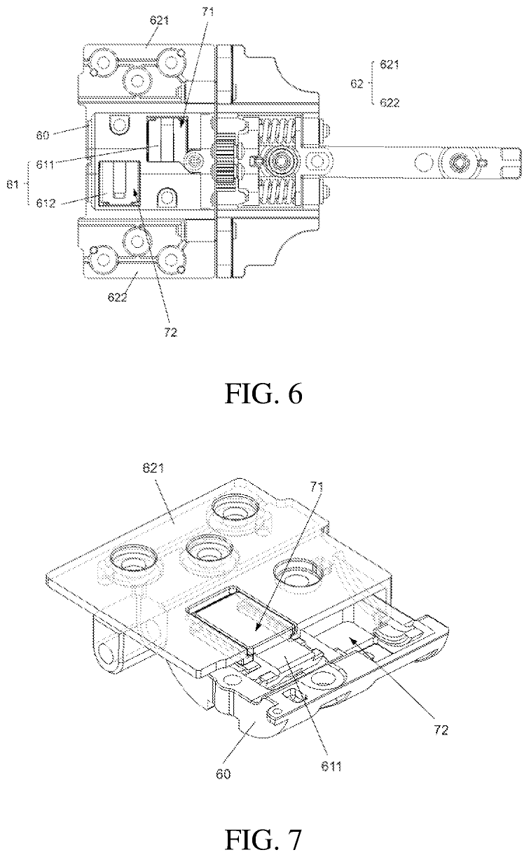

Specifically, as shown in FIG. 6, FIG. 6 is a schematic structural view of a foldable hinge according to an embodiment of the present disclosure. The foldable hinge includes a fixed trestle 60, at least one support mechanism 62, and at least one rotation mechanism 61. Specifically, the support mechanism 62 is disposed on both sides of the fixed trestle 60, and the support mechanism 62 is rotatably connected with the fixed trestle 60. At the same time, an end of the rotation mechanism 61 is fixedly connected with the support mechanism 62, and another end of the rotation mechanism 61 is rotatably connected with the fixed trestle 60.

In the embodiment of the present disclosure, the rotation mechanism 61 is illustrated by a guide slide structure as an example, and the rotation mechanism 61 achieve rotation through the guide slide structure. Specifically, when the rotation mechanism 61 is arranged, the rotation mechanism 61 has two virtual shafts relative to the fixed trestle 60, and each virtual shaft has a virtual axis, for example, a first virtual axis and a second virtual axis. When the rotation mechanism 61 rotates and folds relative to the fixed trestle 60, the rotation mechanism 61 and the support mechanism 62 simultaneously rotate relative to the first virtual axis and the second virtual axis. And during a rotating process, a position of the first virtual axis and a position of the second virtual axis will change with the change of a rotation position of the rotation mechanism 61, so as to ensure that the foldable hinge has better folding performance. In the embodiment of the present disclosure, the first virtual axis may be parallel to the second virtual axis.

Specifically, in the embodiment of the present disclosure, in order to more clearly describe the above different mechanisms, in the following embodiments, the support mechanism 62 is illustrated by including a first support mechanism 621 and a second support mechanism 622 as an example, and the rotation mechanism 61 is illustrated by including a first rotation mechanism 611 and a second rotation mechanism 612 as an example. Herein, the first rotation mechanism 611 may correspondingly refer to a first guide slider, and the second rotation mechanism 612 may correspondingly refer to a second guide slider.

Herein, an upper surface of the first support mechanism 621 and an upper surface of the second support mechanism 622 have same support areas in two corresponding parts thereof, so as to ensure same effective areas acting on the flexible screen, and to ensure that the flexible screen on both sides has good consistency during a bending process.

Furthermore, in the above foldable hinge, a first opening 71 is further defined on the first support mechanism 621, and a second opening 72 is further defined on the second support mechanism 622. Herein, the first opening 71 is not aligned with the second opening 72, that is, the first opening 71 and the second opening 72 are dislocated. At the same time, in the embodiment of the present disclosure, the support mechanism is correspondingly connected with the fixed trestle, so the fixed trestle is provided with same openings at positions thereof corresponding to the first opening 71 and the second opening 72, so as to achieve mutual matching.

Furthermore, in the embodiment of the present disclosure, the rotation mechanism 61 includes a first guide slider 611 and a second guide slider 612 disposed on a side of the first guide slider. Herein, the first guide slider 611 is disposed in the first opening 71, and the second guide slider 612 is disposed in the second opening. When the foldable hinge folds, a rotation axis of the first guide slider 611 relative to the fixed trestle is defined as a first virtual axis O1, and a rotation axis of the second guide slider 612 relative to the fixed trestle is defined as a second virtual axis O2.

Specifically, as shown in FIG. 7, FIG. 7 is a schematic structural view of a partial structure of a foldable hinge according to an embodiment of the present disclosure. In the embodiment of the present disclosure, the foldable hinge is illustrated by half thereof as an example, and a structure of another half is same with the structure shown in FIG. 7. Specifically, the first guide slider 611 is disposed in the first opening 71, and the first guide slider 611 is correspondingly connected with the first support mechanism 621 and the fixed trestle 60. The first opening 71 and the second opening 72 are misaligned. In this way, the linkage of various components of the foldable hinge is realized.

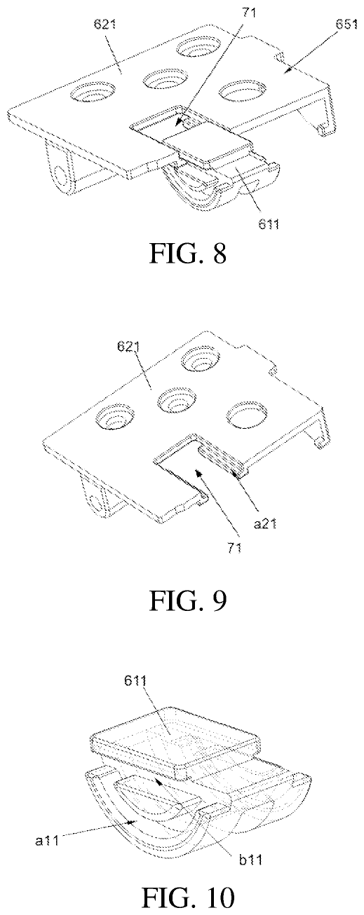

Referring to FIG. 8 to FIG. 11 for detail, FIG. 8 to FIG. 11 are schematic structural views corresponding to a support mechanism, a rotation mechanism, and a fixed trestle of a foldable hinge according to an embodiment of the present disclosure. In the embodiment of the present disclosure, the first support mechanism 621 includes a support surface 651 configured to fix and support the flexible screen thereon.

In the embodiment of the present disclosure, each of the guide sliders of the hinge device is rotatably connected with the fixed trestle by a first slide chute structure, and the support mechanism is rotatably connected with the fixed trestle by a second slide chute structure. Specifically, the first slide chute structure includes first chutes all, and the second slide chute structure includes limit chutes c31.

Specifically, a curvature of the first chute all is different from a curvature of the limit chute c31. Herein, the curvature of the first chute is greater than the curvature of the limit chute c31. Among them, the curvature of the first chute ranges from 20 m−1 to 30 m−1, and the curvature of the limit chute ranges from 15 m−1 to 19 m−1. Preferably, the curvature of the first chute may be 25 m−1, and the curvature of the limit chute is set to 18 m−1.

At the same time, in the embodiment of the present disclosure, in order to ensure that the hinge device has a good rotating effect, when the first chutes all and the limit chutes a31 are arranged, a length of the first chute is less than a length of the limit chute, so as to ensure that the limit chutes on both sides can provide a large sliding distance during a sliding process.

At the same time, the first guide slider 611 is further provided with second chutes b11. Herein, the second chutes b11 are provided adjacent to the first support mechanism 621, and the first chutes all are provided adjacent to the fixed trestle.

When the above first chutes all and the second chutes b11 are arranged, the first chute all is arranged as an arc-shaped chute structure, and the second chute b11 is arranged as a linear chute structure. Accordingly, first rails a21 are further provided in the first opening 71 and on the first support mechanism 621.

At the same time, the fixed trestle 60 are further provided with second rails b00 correspondingly in each of the openings thereof. Herein, each of the second rail b00 is mated with one of the first chutes all of the first guide slider and the first chutes all of the second guide slider. That is, the second rail b00 is slidably disposed in the first chute all. When the first guide slider and the second guide slider of the rotation mechanism rotate, the second guide rail b00 slides along the first chute all, thereby realizing the folding of the foldable hinge.

In the embodiment of the present disclosure, the second rail b00 is also arranged as an arc guide, and an arc length of the second rail b00 is correspondingly greater than an arc length of the first chute all, thereby preventing the first guide slider 611 from sliding out of the first chutes all, which may result in failure of the flexible panel.

Furthermore, the first rail a21 of the first support mechanism 621 is correspondingly inserted into the second chute b11 of the first guide slider 611 when matching. Because the first guide rail a21 and the second chute b11 are linear structures, the first guide rail a21 can penetrate into the second chute b11. When the first support mechanism 621 rotates, the first guide slider 611 can move along the second chute b11 and relative to the first support mechanism 621. In the embodiment of the present disclosure, since the second chute b11 is a linear chute, the first guide slider 611 is translational with respect to the first support mechanism 621 during a moving process. Specifically, during the translational moving process, an end of the first guide slider 611 can be close to or away from an inner side of the first opening 71. At the same time, the upper surface of the first guide slider 611 in the embodiment of the present disclosure is also level with the support surface 651, thereby providing a better supporting effect for the flexible screen.

Furthermore, the first guide slider 611 correspondingly has the first virtual shaft O1 when rotating relative to the fixed trestle 60, and the second guide slider on another side has the second virtual shaft O2 relative to the fixed trestle. The first virtual shaft O1 correspondingly refers to the first virtual axis, and the second virtual shaft O2 correspondingly refers to the second virtual axis. When connection parts rotate, the rotation axis will change with the rotation of the connection parts, and when the axis changes, the motion positions will also change, so as to effectively provide an avoidance space for other components and improve the folding performance of the flexible panel.

Accordingly, an arrangement of the second support mechanism and the second guide slider is similar that of the first support mechanism and the first guide slider, and will not be further explained here. The difference therebetween is that the first guide slider and the second guide slider are arranged at different portions of the fixed trestle.

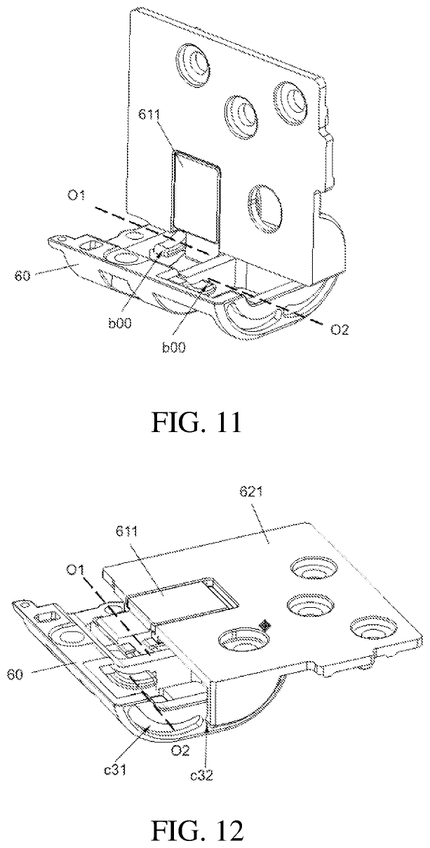

As shown in FIG. 12, FIG. 12 is a schematic structural view of a foldable hinge when unfolding according to an embodiment of the present disclosure. Combined with the structure in FIG. 11, in the embodiment of the present disclosure, the first support mechanism is provided with guide rails c32.

Herein, in the embodiment of the present disclosure, the limit chute c31 is defined on a surface corresponding to a side of the fixed trestle 60, the guide rail c32 is disposed at a side of the support mechanism, and the guide rail c32 can be inserted into the limit chute c31 when connecting and can slide along the limit chute c31, so that the rotation of the support mechanism is limited by the limit chute c31, and a foldable function is realized. Since the guide rail c32 and the first rail a21 are disposed on the support mechanism, the guide rail c32 and the first rail a21 can slide synchronously, thereby ensuring the folding effect of the flexible screen. In the embodiment of the present disclosure, the limit chute c31 is provided as an arc chute.

At the same time, when the support mechanism, the rotation mechanism, and the fixed trestle rotate relative to each other. For example, when the foldable hinge is in the folded state, the guide rail c32 moves away from a center of the fixed trestle; and when the foldable hinge is in a fully unfolded state, the guide rail c32 is close to the center of the fixed trestle.

Furthermore, the guide rail c32 of the first support mechanism 621 is limited to the limit chute c31 of the fixed trestle, and the first guide slider 611 is connected with the first support mechanism through the first chutes all. The first guide slider 611 is connected with the fixed trestle further by the second chutes b11.

Therefore, in the embodiment of the present disclosure, since a side of the first support mechanism 621 is limited by the limit chute c31, during the rotation of the first support mechanism relative to the fixed trestle, the limit chute c31 will provide a force acting on the first support mechanism 621, and the first guide slide 611 is driven by the force to rotate relative to the fixed trestle, the first guide slider 611 is driven to be translational with respect to the first support mechanism along the second chute b11 at the same time, thereby providing the avoidance space for components such as the fixed trestle during translational movement for better folding.

Furthermore, in the embodiment of the present disclosure, during the moving process, the first guide slider 611 will be subjected to simultaneous action of different forces in a plurality of directions, thereby causing the first guide slider to have different relative movements relative to different parts, and then improving the folding effect of the foldable hinge.

In the embodiment of the present disclosure, the guide rail c32 may be provided as a guide pin disposed at an edge of the support mechanism, and the guide pin is inserted into the limit chute c31, so as to achieve mutual match.

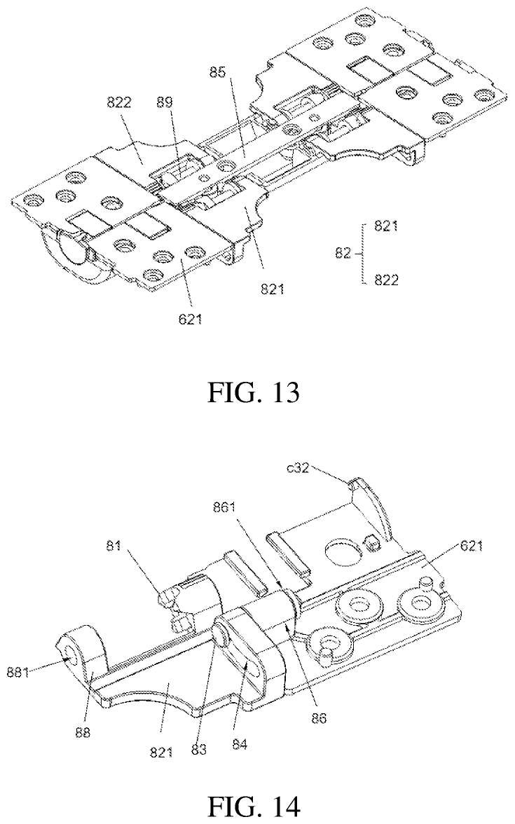

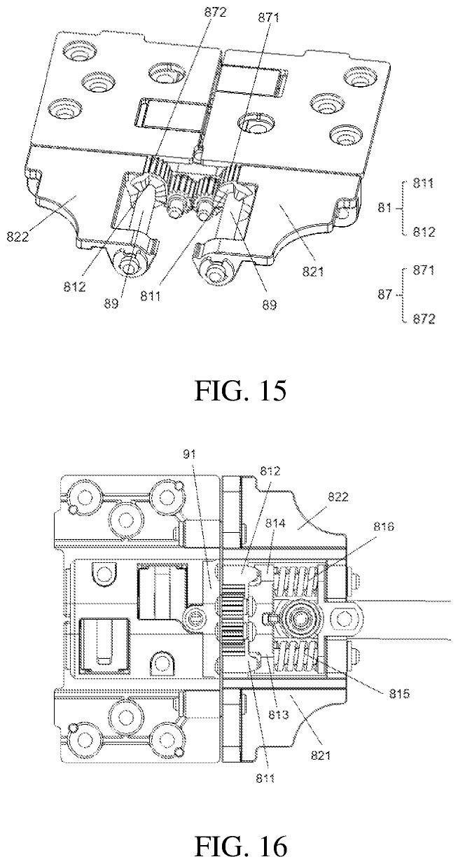

Furthermore, as shown in FIG. 13 to FIG. 15, FIG. 13 to FIG. 15 are schematic structural views of a foldable hinge according to an embodiment of the present disclosure. The hinge device further includes at least one torsion mechanism 82. In the embodiment of the present disclosure, the torsion mechanism 82 may include a first torsion mechanism 821 and a second torsion mechanism 822 symmetrically disposed relative to a central axis of the foldable hinge. There is a gap between the first torsion mechanism 821 and the second torsion mechanism 822 to provide a bending and avoidance space for the flexible screen.

At the same time, the first torsion mechanism 821 is connected to an end of the first support mechanism 621. Specifically, when connecting, an end of the first torsion mechanism 821 is provided with an active groove 84, a corresponding side of the first support mechanism 621 is provided with a fixed end 86 having a connection shaft hole 861. When matching, an end of an axis pin 83 of the foldable hinge is inserted into the active groove 84, and another end of the axis pin 83 is simultaneously inserted into the connection shaft hole 861 of the first support mechanism 621, and the two ends of the axis pin 83 are symmetrically fixed to prevent the axis pin 83 from falling off during the rotation of the foldable hinge, thereby improving the reliability and quality of the flexible device.

Furthermore, since the torsion mechanism and the support mechanism are connected through the axis pins 83, and the torsion mechanism is provided with arc-shaped active grooves 84, when the support mechanism rotates, it will drive the axis pins 83 to move, and then make each axis pin 83 slide in the active groove 84, and make the torsion mechanism move relative to the support mechanism.

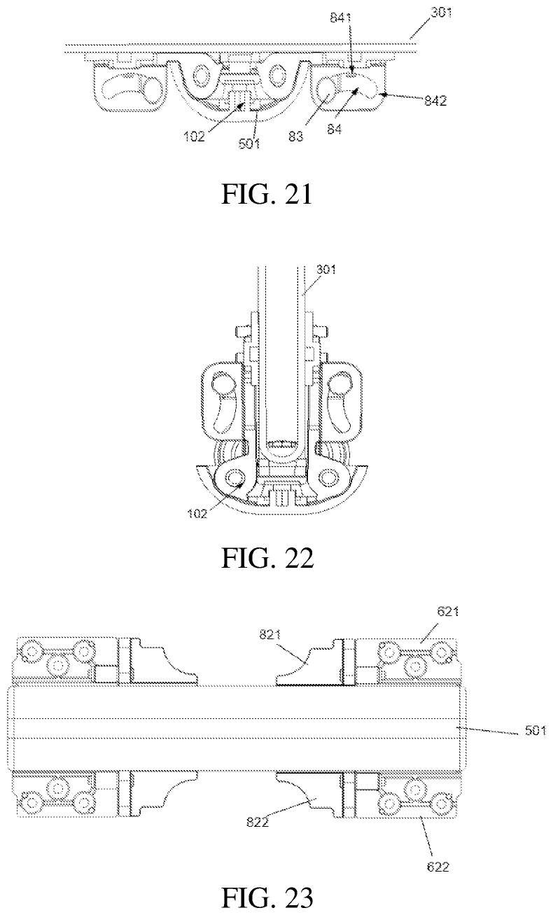

Referring to FIG. 21 for detail, in the embodiment of the present disclosure, when the active grooves 84 are defined, the active groove 84 may be arranged as an arc structure. Specifically, the active groove 84 may include first arc portions 841 and second arc portions 842.

In the embodiment of the present disclosure, the first arc portions 841 are smoothly connected with the second arc portions 842, and the second arc portions 842 are provided on both sides of the first arc portion 841. In the embodiment of the present disclosure, the active groove 84 may be a symmetrical structure. For example, the active groove 84 may be arranged symmetrically relative to a geometric center of the active groove 84.

At the same time, a curvature of the first arc portion 841 is less than a curvature of the second arc portion 842. Preferably, the curvature of the first arc portion 841 is 5.4 m−1, and the curvature of the second arc portion 842 is 75 m−1. In the embodiment of the present disclosure, the first arc portion 841 is a main active path of the axis pin 83. Therefore, an arc length of the first arc portion 841 may be greater than an arc length of the second arc portion 842.

Preferably, the flexible display device further includes a middle support plate 85 disposed between the first torsion mechanism 821 and the second torsion mechanism 822, and the support for the flexible screen is achieved through the support of the middle support plate 85.

Preferably, the torsion mechanism 82 further includes torsion arms 88, main shafts 89, and connection holes 881. Herein, the main shaft 89 is disposed in the connection hole 881, and the torsion arm 88 is disposed at an end of the torsion mechanism 82.

In the embodiment of the present disclosure, each torsion arm is further provided with a cam 81 and a gear 87. Specifically, the cams include a first cam 811 and a second cam 812, and the gears include a first gear 871 and a second gear 872. Herein, the first cam 811 and the first gear 871 are correspondingly disposed on the first torsion mechanism 821, and the second cam 812 and the second gear 872 are correspondingly disposed on the second torsion mechanism 822. The first cam 811 is disposed on a side of the first gear 871, and the second cam 812 is disposed on a side of the second gear 872. When rotating, the first gear 871 and the second gear 872 rotate along opposite directions. The cam is arranged around the connection hole 881.

In the embodiment of the present disclosure, the first gear 871 and the second gear 872 may be set as half gears, and bulges and recesses of the first cam 811 and the second cam 812 are parallel to an axis of the main shaft 89.

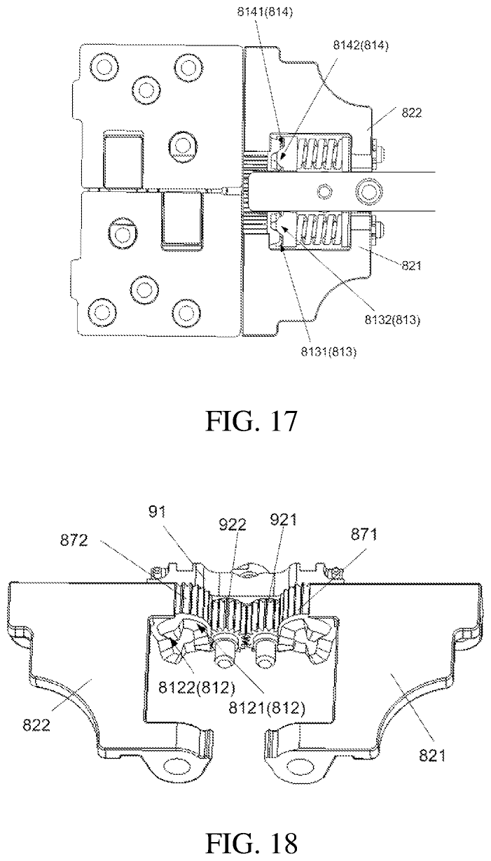

Referring to FIG. 16 and FIG. 17 for detail, FIG. 16 and FIG. 17 are schematic structural views in different directions of a partial structure of a display device according to an embodiment of the present disclosure. Furthermore, the torsion mechanism further includes a third cam 813, a fourth cam 814, a first spring 815, and a second spring 816.

Specifically, the third cam 813 and the fourth cam 814 are each sleeved on one corresponding main shaft. The third cam 813 is arranged opposite to the first cam 811, bulges 8132 of the third cam 813 mesh with recesses 8111 of the first cam 811, recesses 8131 of the third cam 813 mesh with bulges 8112 of the first cam 811, and a flat end of the third cam 813 is in contact with the first spring 815. At the same time, the fourth cam 814 is arranged opposite to the second cam 812, bulges 8142 of the fourth cam 814 mesh with recesses 8121 of the second cam 812, recesses 8141 of the fourth cam 814 mesh with bulges 8122 of the second cam 812, and a flat end of the fourth cam 814 is in contact with the second spring 816. When rotating, the bulges 8112 of the first cam 811 rotate relative to the recesses 8131 of the third cam 813.

In the embodiment of the present disclosure, when the foldable hinge rotates, the torsion mechanism will be correspondingly driven to rotate, and the first cam 811 and the second cam 812 will be driven to rotate. At the same time, the first cam 811 rotates relative to the third cam 813, and the second cam 812 rotates relative to the fourth cam 814. During the rotating process, for example, during the process from unfolding to folding of the foldable hinge, combined with FIGS. 17-18 and FIGS. 21-22, when the foldable hinge is fully unfolded, as shown in FIG. 21, the flexible screen is fully unfolded, a rotation angle of the flexible screen 301 is defined as 0°, and when the foldable hinge is rotated to the angle shown in FIG. 22, the rotation angle of the flexible screen 301 is defined as 90°, in which the rotation angle of the flexible screen 301 is based on the horizontal plane. During the process of the flexible screen folding from 0° to 90°, the first cam is configured to rotate relative to the third cam, which shows that the bulges of the first cam are gradually detached or embedded from the recesses of the third cam.

Furthermore, during a rotating process of the rotation angle of the flexible screen ranging from 0° to 15°, an area of a contact part of the first cam and the third cam gradually changes. With the increase of the rotation angle, an extrusion pressure of the first spring on a side of the third cam gradually increases. At the same time, in the rotating process, different contact states between the first cam and the third cam will further limit the rotation of the torsion mechanism. During a rotating process of the rotation angle of the flexible screen ranging from 15° to 75°, the bulges of the first cam rotate to be in contact with the bulges of the third cam, a pressure angle between the first cam and the third cam is zero at the moment, the first spring and the second spring are in a maximum compression state, and the elastic force reaches the maximum. In this state, hovering of the hinge device is realized.

With further folding of the foldable device, during a rotating process of the rotation angle of the flexible screen ranging from 75° to 90°, the area of the contact part of the first cam and the third cam further changes, for example, the contact between the first cam and the third cam changes from a bulge-to-bulge contact to a bulge-to-recess contact. At this moment, the hinge is provided with a closing force to be automatically closed.

Therefore, in the embodiment of the present disclosure, during folding process of the foldable hinge, the hinge can be hovered and automatically closed in different positions, thereby effectively improving the folding performance of the foldable hinge.

Furthermore, as shown in FIG. 18, FIG. 18 is a schematic structural view of a partial structure of a display device according to an embodiment of the present disclosure. Combined with the structural view in a different direction shown in FIG. 16, the flexible display device further includes at least one avoidance mechanism 91. Herein, an end of the avoidance mechanism 91 is connected to the support mechanism, and the avoidance mechanism 91 is further provided with a third gear 921 and a fourth gear 922. Specifically, the third gear 921 meshes with the fourth gear 922, the first gear 871 meshes with the third gear 921 simultaneously, and the second gear 872 meshes with the fourth gear 922. When the first gear and the second gear of the torsion mechanism rotate, it will correspondingly drive the third gear and the fourth gear to move synchronously. Because the third gear 921 and the fourth gear 922 will rotate correspondingly around the first gear and the second gear, when rotating, the third gear 921 and the fourth gear 922 will make the avoidance mechanism to move, such as making the avoidance mechanism 91 to rise or fall relative to the first gear 871 and the second gear 872, thereby providing avoidance space for the folding of the flexible screen and realizing folding and unfolding of the foldable hinge.

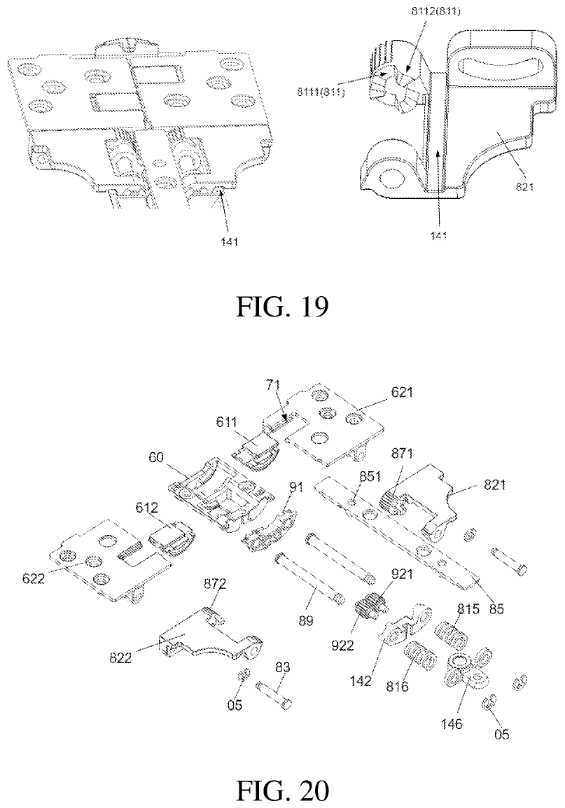

Furthermore, referring to FIG. 19, FIG. 19 is a schematic structural view of a partial structure of another flexible display device according to an embodiment of the present disclosure. Specifically, the flexible display device is further provided with fixing grooves 141 on the torsion mechanism. The fixing groove 141 is connected to a side of the hinge cover 501. The hinge cover 501 is snapped by the fixing grooves 141. Furthermore, in the embodiment of the present disclosure, since the fixed groove 141 is disposed on the torsion mechanism, when the hinge cover 501 is snapped in the fixed grooves, a thickness of the torsion mechanism effectively increase, so that the torsion mechanism has higher strength to prevent problems such as fracture during rotating, thereby effectively improving the reliability of the foldable hinge.

In the embodiment of the present disclosure, since the hinge cover 501 is correspondingly connected to the torsion mechanism of the foldable hinge, when the flexible display device folds, the hinge cover will move accordingly. At the same time, since the rotation mechanism in the embodiment of the present disclosure is provided with chutes with different curvatures, during a sliding process thereof, the rotating axis thereof will change accordingly, thereby making the hinge cover to fall or rise relative to the housing of the flexible display device, while providing avoidance space for other components. Furthermore, a gap between a frame of the housing and the hinge cover after closing the flexible display device is narrowed, and a sealing effect inside the panel is ensured at the same time.

Furthermore, in the embodiment of the present disclosure, the foldable hinge of the flexible display device is a wedge-shaped structure, and the foldable hinge is a bilateral synchronous movement structure, thereby effectively ensuring that the flexible screen will not be squeezed and pulled during the unfolding or folding process thereof. In addition, the foldable hinge has functions such as automatic closing, automatic expansion, and real-time stop during rotation, thereby further improving the folding effect and performance of the flexible display device.

Preferably, referring to FIG. 20, FIG. 20 an exposed view of a flexible display device according to an embodiment of the present disclosure. At the same time, the structures correspond to the above-mentioned components shown in other structural views. The flexible foldable device further includes at least one fixing member 146 connected with the middle support plate 85. Threaded holes 851 are correspondingly provided on the middle support plate 85 and the fixing member 146 to fix the middle support plate 85 and the fixing member 146.

Furthermore, the flexible display device in the embodiment of the present disclosure further includes gaskets 05 and at least one engaging member 142. The engaging member 142 is sleeved on the main shafts 89 to fix the springs. In the embodiment, the engaging member 142 is arranged to include the third cam 813 and the fourth cam 814 and is configured to achieve folding effect through the third cam 813 and the fourth cam 814.

Specifically, in the embodiment of the present disclosure, protruding ends on both sides of the fixing member 146 respectively abut against the first spring 815 and the second spring 816. In this way, one end of the first spring 815 abuts against the third cam 813, and the other end of the first spring 815 abuts against the fixing member 146. Through the limitation of the fixing member 146 and the engaging member 142, the first spring 815 forms an elastic pressure to control the folding effect of the foldable hinge. At the same time, the gaskets 05 mainly fixe the main shafts and the axis pins to improve the reliability of connection.

Furthermore, as shown in FIGS. 21 and 22, FIG. 21 and FIG. 22 are schematic structural views of a flexible display device in different states according to an embodiment of the present disclosure. In the embodiment of the present disclosure, when the flexible screen 301 is fully unfolded, the foldable hinge 102 correspondingly opens, and the axis pin 83 of the torsion mechanism is close to the foldable hinge at this moment; when the flexible screen 301 is fully folded, the axis pin 83 moves in the corresponding active groove 84 during the folding process and moves away from the foldable hinge. At the same time, during the folding process, the hinge cover 501 will rise or fall relative to the housing of the flexible screen, thereby ensuring the folding effect and performance of the flexible display device.

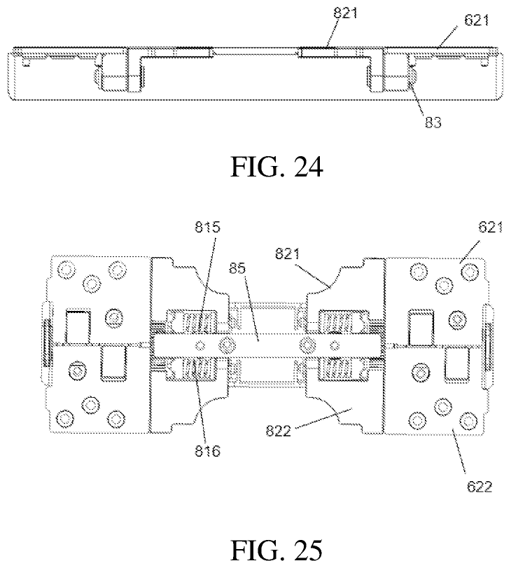

Preferably, as shown in FIG. 23 to FIG. 25, FIG. 23 to FIG. 25 are schematic structural views in different directions of a partial structure of a flexible display device according to an embodiment of the present disclosure. The foldable hinge inside the flexible display device in the embodiment of the present disclosure may be arranged as a symmetrical structure. The foldable hinge is correspondingly disposed on and connected with the frames of the two housings. When the foldable hinge rotates, the flexible screen and the corresponding frames will be flipped, and the flexible display device is folded.

In the above embodiments, the flexible foldable mobile phone is taken as an example to illustrate, preferably, the flexible display device may also be an OLED panel, a mobile phone, a computer, an electronic paper, a monitor, a laptop, a digital photo frame, or other products or components with display and bending or folding functions, and the specific type is not specifically limited.

The hinge devices and flexible display devices according to embodiments of the present disclosure have been described above in detail. Specific examples are used to illustrate the principle and implementation mode of the application in the present disclosure. The illustration of the above embodiments is intended only to assist in understanding the technical solutions and core ideas of the present disclosure. Those of ordinary skill in the art should understand that: they may still modify the technical solutions described in the foregoing embodiments, or replace some of the technical features equivalently, these modifications or replacements do not deviate the essence of the corresponding technical solutions from the scope of the technical solutions according to embodiments of the present disclosure.

1. A hinge device, comprising:
a fixed trestle;
a guide slider disposed on a side of the fixed trestle and rotatably connected with the fixed trestle; and
a support mechanism disposed on a side of the fixed trestle, rotatably connected with the fixed trestle, and slidably connected with the guide slider,
wherein when the hinge device rotates, the support mechanism and the guide slider rotate relative to the fixed trestle, and the support mechanism slide relative to the guide slider; and
wherein the hinge device further comprises a torsion mechanism and a middle support plate, the torsion mechanism comprises a first torsion mechanism and a second torsion mechanism, and the middle support plate is disposed between the first torsion mechanism and the second torsion mechanism.

2. The hinge device according to claim 1, wherein the support mechanism rotates around a first virtual shaft, the guide slider connected with the support mechanism rotate around a second virtual shaft, and the first virtual shaft is parallel to the second virtual shaft.

3. A hinge device, comprising:
a fixed trestle;
a guide slider disposed on a side of the fixed trestle and rotatably connected with the fixed trestle; and
a support mechanism disposed on a side of the fixed trestle, rotatably connected with the fixed trestle, and slidably connected with the guide slider,
wherein when the binge device rotates, the support mechanism and the guide slider rotate relative to the fixed trestle, and the support mechanism slide relative to the guide slider.

4. The hinge device according to claim 3, wherein the support mechanism rotates around a first virtual shaft, the guide slider connected with the support mechanism rotate around a second virtual shaft, and the first virtual shaft is parallel to the second virtual shaft.

5. The hinge device according to claim 3, wherein the guide slider is rotatably connected with the fixed trestle by a first slide chute structure;
the support mechanism is rotatably connected with the fixed trestle by a second slide chute structure; and
the first slide chute structure comprises first chutes, the second slide chute structure comprises limit chutes, and a curvature of each of the first chutes is different from a curvature of each of the limit chutes.

6. The hinge device according to claim 5, wherein the curvature of each of the first chutes ranges from 20 m−1 to 30 m−1, and the curvature of each of the limit chutes ranges from 15 m−1 to 19 m−1.

7. The hinge device according to claim 6, wherein a length of each of the first chutes is less than a length of each of the limit chutes.

8. The hinge device according to claim 3, wherein the support mechanism comprises a first support mechanism and a second support mechanism disposed on a side of the first support mechanism, the first support mechanism has a first opening, the second support mechanism has a second opening, and the first opening and the second opening are dislocated.

9. The hinge device according to claim 8, wherein the guide slider comprises a first guide slider and a second guide slider; and
the first guide slider is disposed in the first opening, the second guide slider is disposed in the second opening, the second virtual shaft which the first guide slider and the second guide slider rotate around changes as rotation of the support mechanism.

10. The hinge device according to claim 9, wherein the first guide slider and the second guide slider are each provided with the first chutes and second chutes thereon, the second chutes are disposed adjacent to the support mechanism, and the first chutes are disposed adjacent to the fixed trestle; and
each of the second chutes is a linear chute, and each of the first chutes is an arc-shaped chute.

11. The hinge device according to claim 9, wherein the first support mechanism and the second support mechanism are each provided with first rails thereon, and the fixed trestle is provided with second rails thereon;
each of the second chutes on the first guide slider is mated with one of the first rails on the first support mechanism, and the first guide slider is configured to be translational with respect to the first support mechanism and along the second chutes thereon;
each of the second chutes on the second guide slider is mated with one of the first rails on the second support mechanism, and the second guide slider is configured to be translational with respect to the second support mechanism along the second chutes thereon; and
each of the first chutes on the first guide slider and the second guide slider is correspondingly mated with one of the second rails on the fixed trestle.

12. The hinge device according to claim 3, further comprising:
a torsion mechanism disposed on at least one side of the fixed trestle and rotatably connected with the fixed trestle,
wherein the support mechanism slides relative to the torsion mechanism by a third slide chute structure.

13. The hinge device according to claim 12, wherein the torsion mechanism is provided with active grooves adjacent to the support mechanism, and each of the active grooves is arc-shaped.

14. The hinge device according to claim 13, wherein each of the active grooves comprises first arc portions and second arc portions, the second are portions are disposed on both sides of each of first arc portions, and the second are portions are smoothly connected with each of first are portions; and
a curvature of each of the first are portions is less than a curvature of each of the second arc portions.

15. The hinge device according to claim 13, wherein the torsion mechanism further comprises axis pins, each of the axis pins comprises an end fixed on the support mechanism and another end inserted into one of the active grooves; and
when the hinge device rotates, the support mechanism is configured to drive the axis pins to slide in the active grooves and to drive the torsion mechanism to move relative to the support mechanism.

16. The hinge device according to claim 12, wherein the torsion mechanism comprises a first torsion mechanism and a second torsion mechanism opposite to the first torsion mechanism, the first torsion mechanism and the second torsion mechanism comprise torsion arms disposed on ends thereof, main shafts, and connection holes; and
the torsion arms are provided with cams and gears, each of the cams is disposed on a side of one of the gears, and each of the cams is disposed around one of the connection holes.

17. The hinge device according to claim 16, wherein the cams comprise a first cam and a second cam, the gears comprise a first gear and a second gear, the first cam and the first gear are disposed on one of the torsion arms of the first torsion mechanism, and the second cam and the second gear are disposed on one of the torsion arms of the second torsion mechanism.

18. The binge device according to claim 3, further comprising an avoidance mechanism,
wherein an end of the avoidance mechanism is connected with the fixed trestle, the avoidance mechanism is provided with a third gear and a fourth gear meshes with each other, and the third gear and the fourth gear each mesh with a corresponding one of the gears on the torsion arms; and
when the hinge device rotates, the first gear and the second gear on the torsion arms are configured to drive the third gear and the fourth gear to rotate, so as to make the avoidance mechanism rise or fall relative to the torsion mechanism.

19. The hinge device according to claim 17, wherein the torsion mechanism further comprises:
a third cam and a fourth cam, each of the third cam and the fourth cam being sleeved on a corresponding one of the main shafts; and
springs, each of the springs being sleeved on a corresponding one of the main shafts and abutting against one of the third cam and the fourth cam,
wherein recesses of the first cam mesh with bulges of the third cam, recesses of the second cam mesh with bulges of the fourth cam, and the bulges rotate relative to the recesses when the torsion mechanism rotates.

20. A flexible display device, comprising:
a flexible screen;
a housing configured to support the flexible screen; and
at least one hinge device, the flexible screen being laid on the hinge device, and the hinge device being connected with the housing;
wherein the hinge device comprises:
a fixed trestle;
a guide slider disposed on a side of the fixed trestle and rotatably connected with the fixed trestle; and
a support mechanism disposed on a side of the fixed trestle, rotatably connected with the fixed trestle, and slidably connected with the guide slider; and
wherein when the binge device rotates, the support mechanism and the guide slider rotate relative to the fixed trestle, and the support mechanism slide relative to the guide slider.
